(19) United States
(12) Patent Application Publication
(10) Pub. No.: US 2004/0018697 A1
(43) Pub. Date: Jan. 29, 2004

(54) Method and structure of interconnection with anti-reflection coating

(76) Inventor: Henry Wei-Ming Chung, Taipei (TW)

Correspondence Address: Thomas T. Moga, Dickinson Wright PLLC, 1901 L Street NW, Suite 800, Washington, DC, 20036, US

(21) Appl. No.: 10/205,222

(22) Filed: Jul. 26, 2002

(51) Int. Cl. H01L 21/76

(52) U.S. Cl. 438/437; 257/437

(57) ABSTRACT

A method and structure for interconnection fabrication by using dielectric anti-reflection coating to improve the photolithographic process. The device's structure comprises a substrate with a Cu or Cu-based alloy formed therein. After planarizing the device, a thin barrier dielectric layer is formed on the substrate. A dielectric anti-reflection coating (DARC) layer is then formed on the barrier dielectric layer. Next, another inter-layer dielectric is formed on the anti-reflective coating layer and a subsequent photoresist layer is formed on the inter-reflection coating layer and patterned by using the underlying DARC layer to reduce the light reflection. By using the structure and method of the present invention, it is possible to decrease the process steps and increase the precision of the photolithographic process.

### FIELD OF THE INVENTION

The present invention relates to semiconductor processes and structures for fabrication of interconnection, and especially to structures and photolithographic processes using dielectric anti-reflection coatings (DARC) to improve its process steps in a damascene based conductive layer.

### BACKGROUND OF THE INVENTION

When building an integrated circuit operating with desired action, it is necessary to fabricate many active devices on a single semiconductor substrate. Each of the devices must be electrically isolated from the others to ensure their individual function, and specific devices must be electrically interconnected to implement the whole desired circuit function. The trend for semiconductor fabrications to have higher performance and a higher integration degree have recently made the designs of microcircuit devices finer, and thus multi-layer wiring structures are essentially required for designing and manufacturing VLSI and ULSI semiconductor devices.

In order to build the interconnection and contact among all the active devices, a metallization process is employed. On the semiconductor substrate, with build in active devices and underlying interconnect layer, there is a metal plug pattern, formed by a dielectric layer deposition, followed by photolithography and etching for patterning. After stripping the photoresist layer from the plug pattern, a metal plug is deposited on the semiconductor substrate. Utilizing a metal patterning to form the interconnecting lines performs a conventional multilevel-interconnect technology.

Due to the metal patterning difficulty, a new technique named the damascene process has been developed to lead in multilevel-interconnect technology. The damascene process employs the inter-layer dielectric patterning instead of the metal patterning. That is, after the interconnective plug process, another inter-layer dielectric is deposited, then the metal line pattern is opened in this inter-layer dielectric. Afterwards, an interconnection metal deposition followed by an etching back is performed to refill the metal trenches and form one level of interconnection. Moreover, another improved method called the dual damascene process is applied for simplifying the manufacturing processes.

Before the photoresist can aid small image patterning on the substrate, an anti-reflection coating (ARC) is deposited onto the substrate to increase the precision of the photolithography process. An ARC cuts down on light scattering from the surface of the lower layer, minimizes standing waves effects, improves the image contrast and makes a more planarized photoresist layer. Nevertheless, there are several disadvantages associated with the use of an ARC layer. For example, an additional ARC layer will complicate the fabrication processes. Moreover, sometimes a thin oxide layer is needed to form on the ARC layer to further protect the ARC layer during rework of the upper photoresist layer. The thin oxide layer will further increase the process steps. Therefore, a need exists for photolithographic technology to using an ARC layer but not to complicate the fabrication processes.

### SUMMARY OF THE INVENTION

An objective of the present invention employs a semiconductor device comprising an interconnection pattern with dielectric anti-reflective coating (DARC) fabricated under the inter-layer dielectric that should be etched by using a patterned photoresist.

Another objective of the present invention is an efficient, cost-effective method of manufacturing a semiconductor device having an interconnection pattern with fewer process steps, better trench and via profile and less capacitance contribution with a new composite layer of diffusion barrier dielectric/DARC layer.

Additional objectives, advantages and other features of the present invention will be set forth in part in the description which follows and in part will become apparent to those having ordinary skill in the art upon the following examination or may be learned from the practice of the invention. The objectives and advantages of the invention may be understood and obtained as particularly pointed out in the appended claims.

According to the present invention, the foregoing and other objectives are achieved by a semiconductor device comprising: a substrate, in which designed active devices are built. A planarized inter-layer dielectric is deposited on the substrate with Cu-containing layers formed therein. A thin barrier dielectric is deposited on the interlayer dielectric and the Cu-containing layer. A DARC layer is then formed on the surface of the barrier dielectric.

Afterwards, another inter-layer dielectric is deposited on the DARC layer to provide the isolation between different conductive lines. Next, a photoresist layer is patterned on the inter-layer dielectric by a standard process. During patterning of the photoresist layer, the underlying DARC layer will absorb most of the radiation and therefore reduce the standing wave effects. Next, repeatable processes such as Cu-containing layers are formed in the second inter-layer dielectric.

In another embodiment of the present invention, since the DARC layer is combined with the barrier dielectric layer, it is possible to replace this composite layer with a single dielectric layer to further decrease the processing steps.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross sectional view of a portion of an integrated circuit structure according to a conventional process; and

FIGS. 2 through 5 schematically depict cross sectional views of a method to form a dielectric anti-reflection coating according to the present invention.

### DETAILED DESCRIPTION OF THE PREFERRED EMBODIMENT

Reference will now be made in detail to the preferred embodiment of the present invention, examples of which are illustrated in the accompanying drawings. The method described herein includes many process steps well know in the art such as photolithography, etching or chemical vapor deposition which will not be discussed in detail. In addition, numbers in all the figures always denote the same element to further increase understanding.

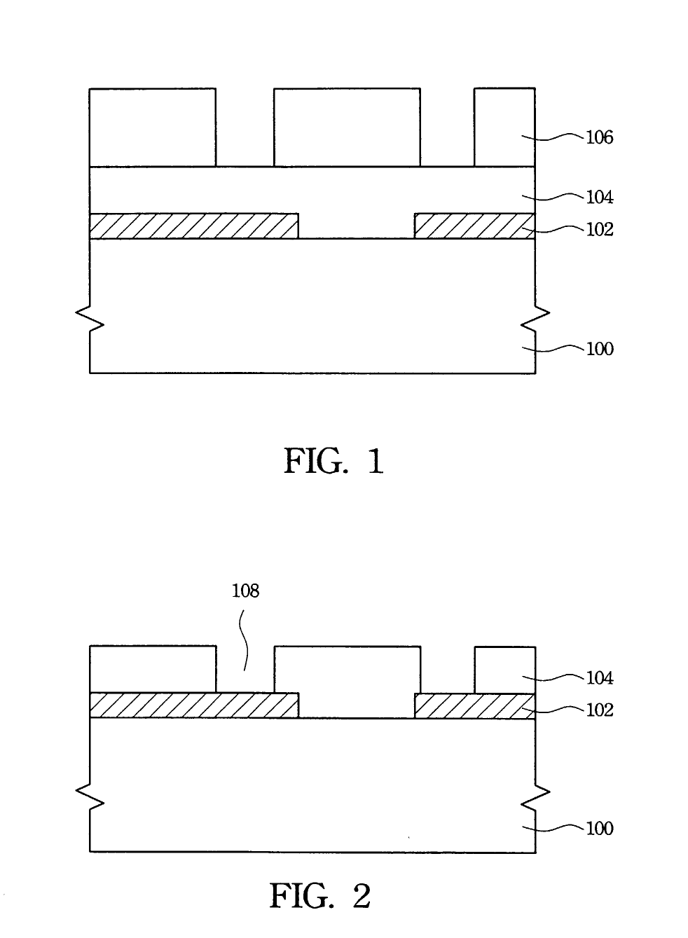

Referring to FIG. 1, the figure shows a cross sectional view of a semiconductor substrate to form multilevel interconnection according to the present invention. In this figure, a substrate 100 is built into the designed active devices. The conductive layer 102 represents electrodes of those designed active devices or an underlying interconnect layer. Those active devices, such as transistors, resistors and capacitors are not shown in the figures for the cross-sectional view of the semiconductor substrate. Without limiting the spirit and the scope of the present invention, only the metallization processes and the interconnect line profile are illustrated.

As can be seen in this figure, a planarized inter-layer dielectric 104 is deposited on the conductive layer 102 and the substrate 100 to provide the isolation between interconnect layer and active devices or between different interconnect layers. The inter-layer dielectric 104 is formed of the dielectric materials such as silicon nitride or silicon oxide including phosphosilicate glass (PSG), borosilicate glass (BSG), borophosphosilicate glass (BPSG), tetra-ethyl-ortho-silicate oxide (TEOS), and so on. The suitable method to form the inter-layer dielectric 104 can be low-pressure chemical vapor deposition (LPCVD) or plasma-enhanced chemical vapor deposition (PECVD). Next, the photoresist 106 with the plug pattern, either the contact plug or the via plug, is formed on the inter-layer dielectric 104 by using the standard process of photolithography, comprising photoresist coating, exposure and development process.

Referring now to FIG. 2, an anisotropic etching process such as the reactive ion etching (RIE) process is carried out to form the plug regions 108 in the inter-layer dielectric 104. The plasma source containing oxygen and fluorocarbon such as CF₄, CHF₃, C₂F₆ or C₃F₈ will be the preferable etching gases for both oxide and nitride dielectric. Next, the photoresist 106 is removed and wet etched.

Before proceeding to the subsequent processes, since Cu-based “back-end” metallization will have the possibility of Cu diffusion into the underlying semiconductor, typically silicon, resulting in semiconductive properties degradation thereof, as well as poor adhesion of the deposited Cu or of the Cu-based alloy layer. As a consequence of these phenomena associated with the copper-based metallization layer, it is generally necessary to provide adhesion improvement and/or a diffusion barrier layer in between the semiconductor substrate and the overlying copper-based metallization layer.

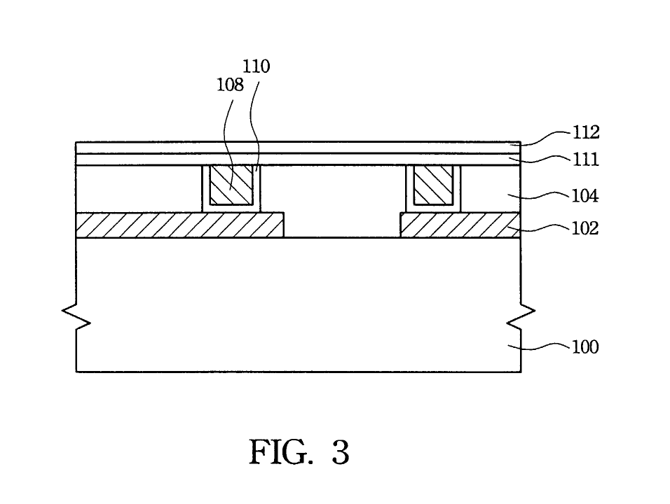

Referring to FIG. 3, after removal of the photoresist 106, an adhesion/barrier metal 110 is formed over the plug regions 108 with a thickness between about 100 to 400 Å. The adhesion/barrier metal 110 includes, e.g., titanium (Ti), tungsten (W), tantalum (Ta), and tantalum nitride (TaN). Afterwards, a layer of Cu or Cu-based alloy is deposited by a conventional electroplating technique to fill in the plug regions 108. In order to ensure complete filling of the plug regions, the Cu-containing layer is deposited as a blanket layer of excess thickness in order to overfill the plug regions 108 and cover the upper surface of the barrier metal 110. Next, the entire excess metal thickness is removed by a chemical mechanical polishing (CMP) process utilizing an alumina-based slurry and using the inter-layer dielectric 104 as an etch stop. After the etching back process for global planarization, a barrier dielectric 111 is deposited on the inter-layer dielectric 104 and the Cu-containing layer. The barrier dielectric 111 is formed from the dielectric materials such as silicon nitride (SiN), silicon carbide (SiC), and SiCₓN_{y}. The suitable method to form the barrier dielectric 106 can be LPCVD or PECVD.

After that, according to the present invention, an anti-reflective coating (ARC) layer 112 is formed on the surface of the barrier dielectric 111. This is performed to benefit the subsequent inter-layer dielectric patterning (not shown in FIG. 3). The material of the ARC layer 112 is selected depending on the wavelength of the light source used at the later exposure step. For example, due to the different wavelength scopes of the absorption lines, a double film of titanium and titanium nitride (Ti/TiN) is a preferable ARC material for I-line source, and silicon oxynitride (SiON) is preferable for deep ultra-violet (DUV) rays. In the preferred embodiment of the present invention, the ARC layer 112 is formed of silicon oxynitride. The dielectric ARC (DARC) layer 112 can be formed by PECVD or LPCVD at a temperature of about 300 to 800° C. Heating the silicon oxide in a NO or N₂O ambient can also form the dielectric ARC layer 112. With the DARC layer 112, the precision of the later exposure will be increased, and the interconnecting line pattern will be formed more accurately.

In another embodiment of the present invention, the composite layer includes the barrier layer 111 and the DARC layer 112 can be replaced by a single dielectric layer to further decrease the processing steps. It should be noted that the dielectric layer has both a barrier function for underlying Cu metal and an anti-reflective coating function for subsequent photolithography process.

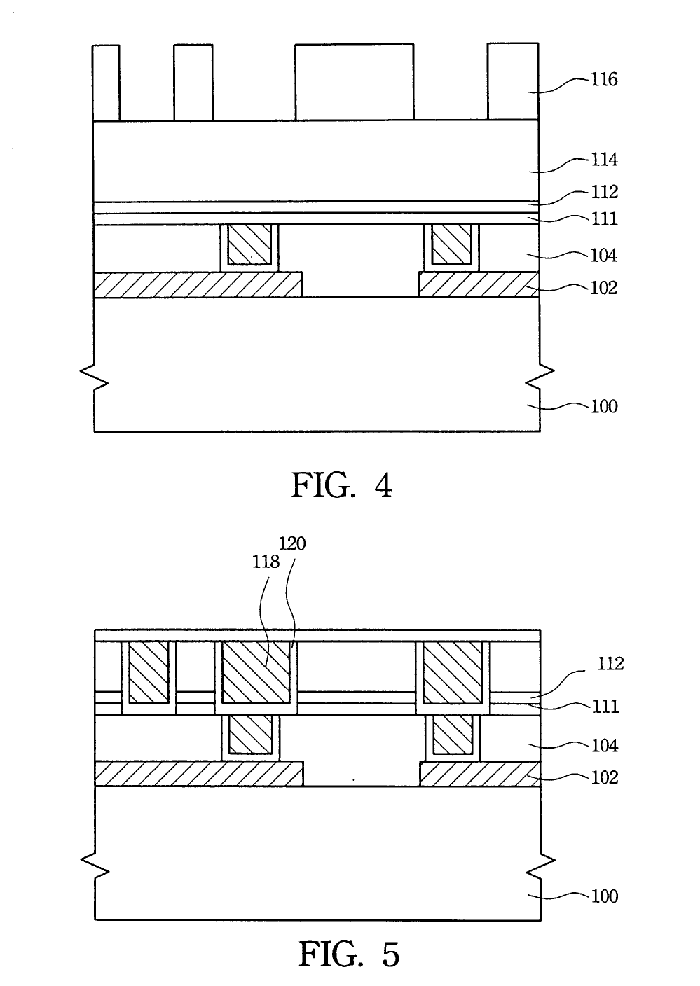

Turning next to FIG. 4, according to the present invention, another inter-layer dielectric 114 is deposited on the DARC layer 112 to provide the isolation between different conductive lines. The inter-layer dielectric 114 is also formed from the dielectric materials such as silicon oxide including PSG, BSG, BPSG, TEOS, and so on. The suitable method to form the inter-layer dielectric 114 can be LPCVD or PECVD. Next, the photoresist 116 is now patterned on the inter-layer dielectric 114 with the pattern of the interconnecting conductive lines by a standard photolithography process. It should be noted that although the DARC layer 112 is under the inter-layer dielectric 114, the DARC layer 112 will also absorbs most of the radiation that penetrates the photoresist 116 during the photolithography exposure process since the inter-layer dielectric 114 made of oxide material is transparent. Standing wave effects are substantially reduced, as there is much less reflection from the underlying metal lines or electrodes.

Afterwards, an anisotropic etching process is performed to form the plug regions 118 in the inter-layer dielectric 114, and then the photoresist 116 is removed and wet etched as shown in FIG. 5. Next, the adhesion/barrier metal 120 and Cu-containing layer is formed over the plug regions 118 sequentially. In a subsequent step, the substrate is subjected to a process for planarizing the plated surface, as by a CMP process similar to the step illustrated in FIG. 3. Furthermore, another barrier dielectric 122 is deposited on the inter-layer dielectric 114 and the Cu-containing layer with silicon nitride, silicon carbide, and SiCₓN_{y} similar to the step illustrated in FIG. 3.

The present invention is applicable to the formation of various types of metallization patterns, illustratively, but not limited to, Cu and/or Cu-based alloys. The present invention is particularly applicable to semiconductor device manufacturing having sub-micron dimensioned metallization features and high aspect ratio openings. In summary, the DARC layer is on the barrier dielectric and the underlying Cu metal, in which there is no additional thin oxide layers atop DARC; secondly, there is no extra thin oxide layer/DARC needed on the subsequent inter-layer dielectric for the photoresist patterning.

By using the features of the present invention, the precision of the photolithography process will increase, i.e., result in better trench and via profile. Furthermore, the processing steps will be reduced and the throughput will be increased. Lastly, since thinner Cu diffusion barrier dielectric usually has a high dielectric constant, the combined barrier dielectric/DARC layer will have less capacitance contribution due to the dielectric constant reduction.

As is understood by a person skilled in the art, the foregoing preferred embodiments of the present invention are illustrations of the present invention rather than limitations of the present invention. It is intended to cover various modifications and similar arrangements included within the spirit and scope of the appended claims, the scope of which should be accorded the broadest interpretation so as to encompass all such modifications and similar structure.

What is claimed is:

1. A semiconductor device, said semiconductor device comprising:
a substrate, wherein a conductive layer is formed therein;
a first insulating layer formed on said substrate and said conductive layer;
an anti-reflective coating layer formed on said first insulating layer;
an inter-layer dielectric formed on said anti-reflective coating layer; and
a photoresist formed on said inter-layer dielectric and patterned to form interconnection lines.

2. The semiconductor device according to claim 1, wherein said conductive layer is a Cu or Cu-based alloy layer.

3. The semiconductor device according to claim 1, wherein said substrate containing said conductive layer is global planarized by chemical mechanical polishing (CMP).

4. The semiconductor device according to claim 1, wherein said first insulating layer comprises silicon oxide or silicon nitride.

5. The semiconductor device according to claim 1, wherein said first insulating layer is a barrier layer for said underlying conductive layer.

6. The semiconductor device according to claim 1, wherein said anti-reflective coating layer comprises silicon oxynitride (SiON).

7. The semiconductor device according to claim 1, wherein said inter-layer dielectric is formed by silicon oxide including phosphosilicate galss (PSG), borosilicate glass (BSG), borophosphosilicate glass (BPSG), tetra-ethyl-ortho-silicate oxide (TEOS).

8. A method for forming an interconnection pattern in a semiconductor device, said method comprising:
forming a first insulating layer on a substrate, wherein a conductive layer is formed in said substrate;
forming an anti-reflective coating layer on said first insulating layer;
forming an inter-layer dielectric on said anti-reflective coating layer; and
forming a photoresist layer on said inter-layer dielectric and patterning said photoresist layer.

9. The method according to claim 8, wherein said conductive layer is a Cu or Cu-based alloy layer.

10. The method according to claim 8, wherein said substrate containing said conductive layer is global planarized by chemical mechanical polishing (CMP).

11. The method according to claim 8, wherein said anti-reflective coating layer comprises silicon oxynitride (SiON).

12. The method according to claim 8, wherein said inter-layer dielectric is formed by silicon oxide including phosphosilicate galss (PSG), borosilicate glass (BSG), borophosphosilicate glass (BPSG), tetra-ethyl-ortho-silicate oxide (TEOS).
